(19) United States
(12) Patent Application Publication
(10) Pub. No.: US 2009/0085131 A1
(43) Pub. Date: Apr. 2, 2009

(54) SEMICONDUCTOR DEVICE AND MANUFACTURING METHOD THEREOF

(75) Inventor: Yoshihisa MATSUBARA, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, Kanagawa (JP)

(21) Appl. No.: 12/237,433

(22) Filed: Sep. 25, 2008

(30) Foreign Application Priority Data
Sep. 28, 2007 (JP) 2007-255385
Aug. 7, 2008 (JP) 2008-203793

(51) Int. Cl. H01L 21/28; H01L 29/78

(52) U.S. Cl. 257/411; 438/585; 257/E29.255; 257/E21.19

(57) ABSTRACT

The semiconductor device includes: a semiconductor substrate; a diffusion layer provided in the semiconductor substrate; a gate insulation film provided on the semiconductor substrate; a gate electrode provided on the gate insulation film; and a Ni silicide layer selectively provided on the diffusion layer, and a metal cap film having Co as a main component is selectively provided on the Ni silicide layer.

This application is based on Japanese patent applications No. 2007-255385/2008-203793, the contents of which are incorporated hereinto by reference.

### BACKGROUND

1. Technical Field

The present invention relates to a semiconductor device and its manufacturing method, and especially, to a semiconductor device including a transistor having a metallic silicide layer on a diffusion layer, and manufacturing method thereof.

2. Related Art

There has been adopted a transistor with a salicide structure using a Ni silicide in order to reduce a diffusion-layer resistance and a resistance of a gate electrode along with finer-line processes of LSIs.

A Japanese Laid-Open patent publication No. H07-038104 has disclosed a technology in which, in a transistor with a salicide structure using such a Ni silicide, Ni is prevented from being oxidized during annealing for silicide formation to form an insulation film. Concretely, by a configuration in which Ni and TiN are firstly sputtered all over the surface in this order, annealing for silicide formation is executed to form Ni silicide, and TiN and unreacted Ni are sequentially removed, an insulation film is prevented from being formed by oxidization of Ni during annealing for silicide formation.
[Patented document 1] Japanese Laid-Open patent publication No. H07-038104

However, we have now discovered that in addition to a problems described in the Japanese Laid-Open patent publication No. H07-038104, there is easily caused agglutination reaction of Ni silicide on the diffusion layer in a transistor with a salicide structure using Ni salicide, when the film thickness of a Ni silicide film is reduced, or the width of a diffusion layer becomes small.

Hereinafter, the agglutination reaction will be explained, referring to drawings.

FIG. 19A and FIG. 19B are views explaining the agglutination reaction. FIG. 19A shows a transistor with a salicide structure using Ni silicide before agglutination reaction is caused, and FIG. 19B shows a transistor with a ciliside structure, which uses Ni silicide, after the agglutination reaction is caused.

In FIG. 19A, a semiconductor device 200 has a transistor 220 formed on a P-type silicon substrate 202, and an element isolation film 206. The transistor 220 has: an N-type diffusion layer region 204; a Ni silicide layer 208 provided on the N-type diffusion layer region 204; a gate insulation film 212; a gate electrode 210; a Ni silicide layer 210 formed on the gate electrode; and a side-wall insulation film 216 provided on the side wall of the gate electrode 214.

Before the agglutination reaction of Ni silicide takes place, the Ni silicide layer 208 is continuously provided on the N-type diffusion layer 204 as shown in FIG. 19A.

However, when the agglutination reaction of Ni silicide takes place by the subsequent heat-treating and the like (annealing processing after ion injection after opening a contact hole, and heat-treating caused by barrier metal formation before forming a contact plug), a Ni silicide layer 208′ on the N-type diffusion layer 204 is divided into a plurality of isolated regions, as shown in FIG. 19B. In such a state, there is caused a problem that, as a plurality of divided Ni silicide layers 208′ are connected by the N-type diffusion layer 204 with a higher resistance than that of the Ni silicide layer 208′, the layer resistance of the diffusion layer is increased in comparison with a state, shown in FIG. 19A, in which the agglutination reaction has not been caused.

### SUMMARY

Considering the above-described problem, in one embodiment, there is provide a semiconductor device, comprising: a semiconductor substrate;a diffusion layer provided in said semiconductor substrate; a gate insulation film provided over said semiconductor substrate; a gate electrode provided over said gate insulation film; and a metallic silicide layer having Ni as a main component which is selectively provided over said diffusion layer, wherein there is selectively provided a metal cap film which has Co as a main component, over said silicide layer.

According to the above-described semiconductor device of the present invention, there may be stably obtained a low layer resistance because a metal cap film having Co as a main component is selectively provided on the metallic silicide layer having Ni as a main component on the diffusion layer, and, metallic silicide layer having Ni as a main component is electrically connected through the metal cap film selectively provided in the upper layer of the metallic silicide layer having Ni as a main component even when the agglutination reaction of the metallic silicide layer having Ni as a main component is caused to generate a state in which the metallic silicide layer is divided into parts by the diffusion layer.

Moreover, in another embodiment, there is provided a method of manufacturing a semiconductor device, comprising: forming a gate insulation film over a semiconductor substrate; forming a gate electrode over said gate insulation film; forming a diffusion layer in the neighborhood of said gate electrode; forming selectively a metallic silicide layer having Ni as a main component over said diffusion layer; and growing selectively a metal cap film having Co as a main component over said metallic silicide layer.

According to the above-described method of manufacturing a semiconductor device of the present invention, there may be stably obtained a low layer resistance, because a metal cap film having Co as a main component is selectively grown on a metallic silicide layer having Ni as a main component on a diffusion layer, and, the metallic silicide layer having Ni as a main component is electrically connected through the metal cap film selectively provided in the upper layer of the metallic silicide layer having Ni as a main component even when the agglutination reaction of the metallic silicide layer having Ni as a main component is caused to generate a state in which the metallic silicide layer is divided into parts by the diffusion layer.

According to the present invention, a low layer resistance may be stably obtained in a transistor having a metallic silicide layer, which has Ni as a main component, on a diffusion layer.

### BRIEF DESCRIPTION OF THE DRAWINGS

The above and other objects, advantages and features of the present invention will be more apparent from the following description of certain preferred exemplary embodiments taken in conjunction with the accompanying drawings, in which:

FIG. 1 is a cross sectional view of a semiconductor device according to a first exemplary embodiment of the present invention;

FIG. 2 is a cross sectional view of a semiconductor device according to the first exemplary embodiment of the present invention;

FIGS. 3A and 3B show process cross sectional views for explaining a method of manufacturing the semiconductor device according to the first exemplary embodiment of the present invention;

FIGS. 4A and 4B show process cross sectional views for explaining a method of manufacturing the semiconductor device according to the first exemplary embodiment of the present invention;

FIGS. 5A and 5B show process cross sectional views for explaining a method of manufacturing the semiconductor device according to the first exemplary embodiment of the present invention;

FIG. 6 is a process cross sectional view for explaining a method of manufacturing the semiconductor device according to the first exemplary embodiment of the present invention;

FIG. 7 is a cross sectional view of a semiconductor device according to a second exemplary embodiment of the present invention;

FIG. 8 is a cross sectional view of a semiconductor device according to the second exemplary embodiment of the present invention;

FIG. 9 is a cross sectional view of a semiconductor device according to a third exemplary embodiment of the present invention;

FIG. 10 is a cross sectional view of a semiconductor device according to the third exemplary embodiment of the present invention;

FIG. 11 is a cross sectional view of a semiconductor device according to a fourth exemplary embodiment of the present invention;

FIG. 12 is a cross sectional view of a semiconductor device according to the fourth exemplary embodiment of the present invention;

FIG. 13 is a cross sectional view of a semiconductor device according to a fifth exemplary embodiment of the present invention;

FIG. 14 is a cross sectional view of a semiconductor device according to the fifth exemplary embodiment of the present invention;

FIGS. 15A and 15B are process cross sectional views for explaining a method of manufacturing the semiconductor device according to the fifth exemplary embodiment of the present invention;

FIGS. 16A and 16B are process cross sectional views for explaining a method of manufacturing the semiconductor device according to the fifth exemplary embodiment of the present invention;

FIG. 17 is a cross sectional view of a semiconductor device according to a sixth exemplary embodiment of the present invention;

FIG. 18 is a cross sectional view for a semiconductor device according to the sixth exemplary embodiment of the present invention; and

FIGS. 19A and 19B are views for explaining a subject of the present invention.

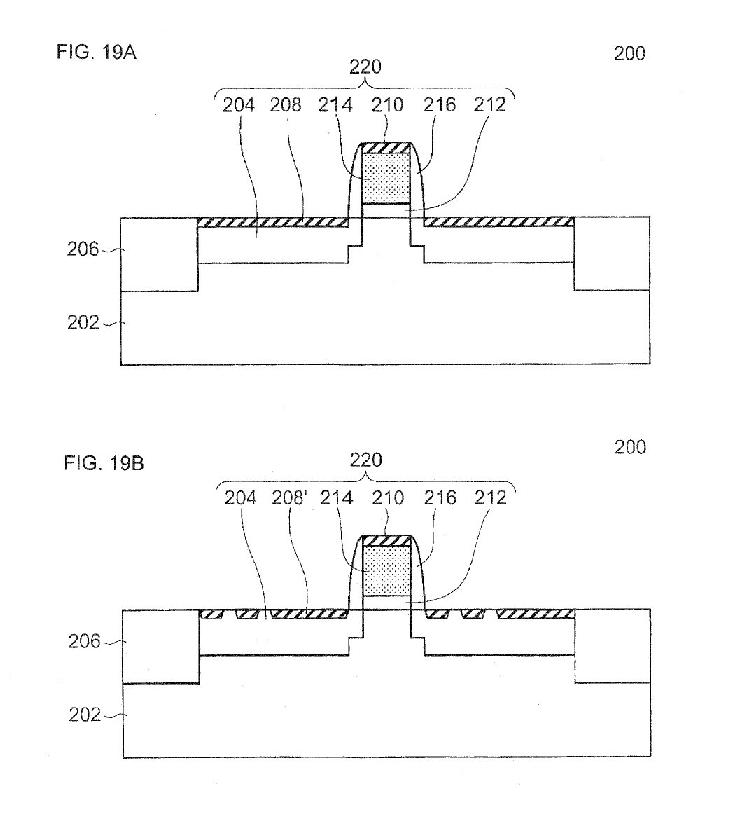

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Exemplary Embodiment

A first exemplary embodiment according to the present invention will be explained, referring to drawings.

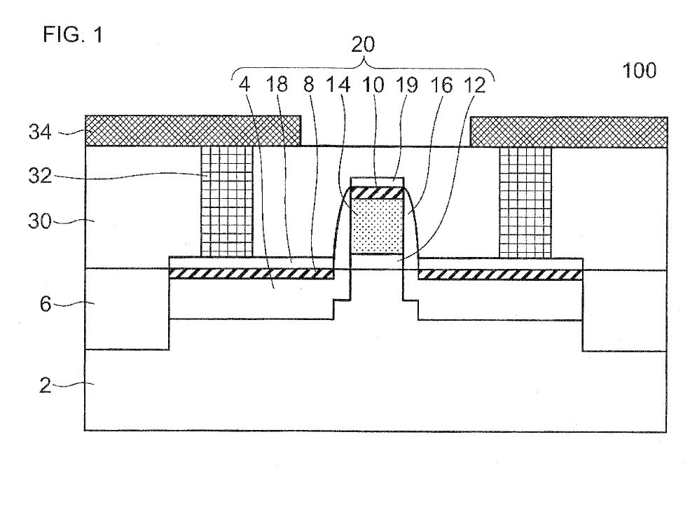

FIG. 1 is a view showing the first exemplary embodiment according to the present invention. In FIG. 1, a semiconductor device 100 has an N-channel transistor (transistor) 20 and an element isolation insulation film 6, which are formed on a P-type silicon substrate (semiconductor substrate) 2. The N-channel transistor 20 has: an N-type diffusion layer 4 (diffusion layer); a Ni silicide layer (metallic silicide layer) 8 provided on the N-type diffusion layer 4; a gate insulation film 12; a gate electrode 14; a Ni silicide layer 10 formed on the gate electrode 14; and a side-wall insulation film 16 provided on the side wall of the gate electrode 4. The gate electrode 14 is formed in, for example, polysilicon.

A Ni silicide layer 8 is continuously provided on the N-type diffusion layer 204, and, selectively, a cap metal film 18 (for example, CoWP) is formed on the Ni silicide layer 8. Moreover, a cap metal film 19 (for example, CoWP) is selectively formed on the Ni silicide layer 10. Here, the above-described N silicide layer may include Pt (that is, a metallic silicide layer having Ni as a main component). A temperature at which there is not seen an increase in the resistance by heat-treating is improved from 500° C. to about 550° C. by adding Pt of from about 1 atom % to about 3 atom % into Ni silicide. Moreover, selective growth of CoWP is possible because there are no large changes in the electro-negativity by adding Pt of not more than about 5 wt % into Ni silicide.

Moreover, the semiconductor device 100 has the N-channel transistor 20, and an insulating interlayer 30 provided on the element isolation insulation film 6. In the insulating interlayer 30, there is provided a contact plug 32 to be connected to the N-type diffusion layer 4. On the insulating interlayer 30, there is provided an interconnect 34 to be connected to a contact plug 32.

Then, a method of manufacturing the semiconductor device 100 according to the above-described exemplary embodiment will be explained, referring to drawings.

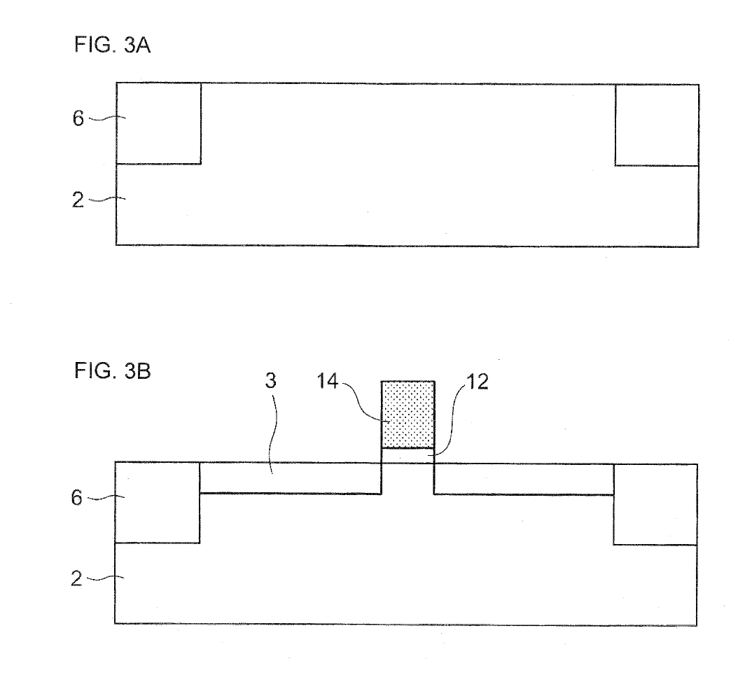

FIG. 3 through FIG. 6 are views which explain a method of manufacturing the semiconductor device 100 according to the present exemplary embodiment.

Firstly there is formed the element isolation insulation film 6 on the P-type silicon substrate 2, as shown in FIG. 3A, for example, by shallow trench isolation.

Then, there are formed the gate insulation film 12 and the gate electrode film (for examples poly-silicon film) on the P-type silicon substrate 2, and, using the known lithography system technology, the gate electrode 14 is formed by patterning of the gate electrode film in such a way that only a predetermined region is left. Moreover, N-type impurities are introduced by ion injection using the gate electrode 14 as a mask, and an N-type extension 3 is formed to obtain a structure shown in FIG. 3B.

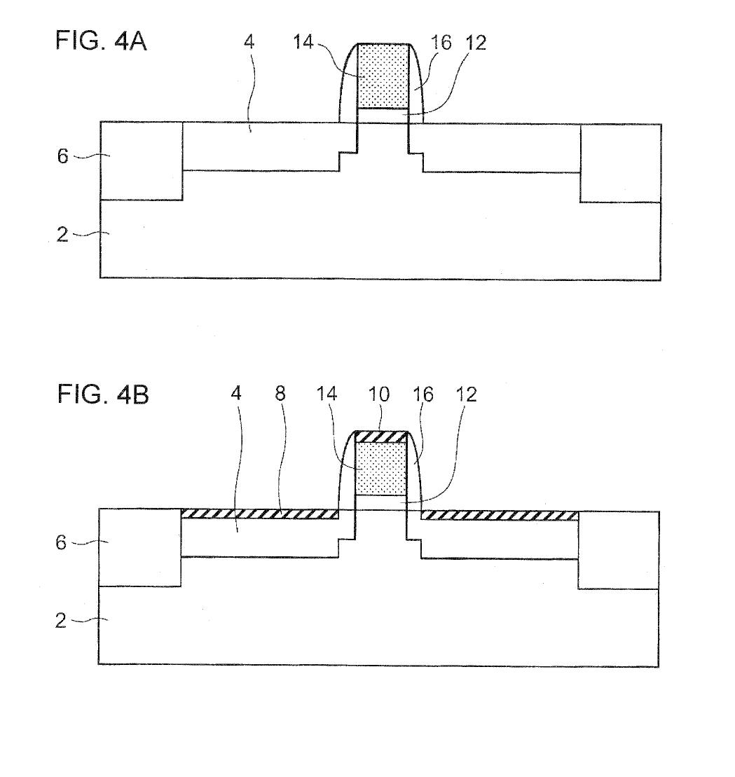

Then, the side-wall insulation film 16 is formed on the side wall of the gate electrode 14, ions are injected, using the gate electrode 14 and the side wall insulation film 16 as a mask, N-type impurities are introduced to form the N-type diffusion layer 4, and a structure shown in FIG. 4A is obtained.

Then, a Ni film is formed all over the surface by sputtering and the like, and annealing for silicidation is performed to cause silicide reaction between silicon and the Ni film in the silicon substrate and the gate electrode. Subsequently, a Ni silicide film 8 is selectively formed on the N-type diffusion layer 4, as shown in FIG. 4B, by removing the unreacted Ni film formed on the element isolation insulation film 6 and the side-wall insulation film 16 using wet etching and the like, and a Ni silicide film 10 is selectively formed on the gate electrode 14. Here, when Pt is added to the Ni silicide layer, Pt can be added to the Ni silicide layer in the process forming the Ni film by sputtering and the like by causing a silicide reaction after forming a Ni layer including Pt through co-sputtering using a target having of Ni including Pt.

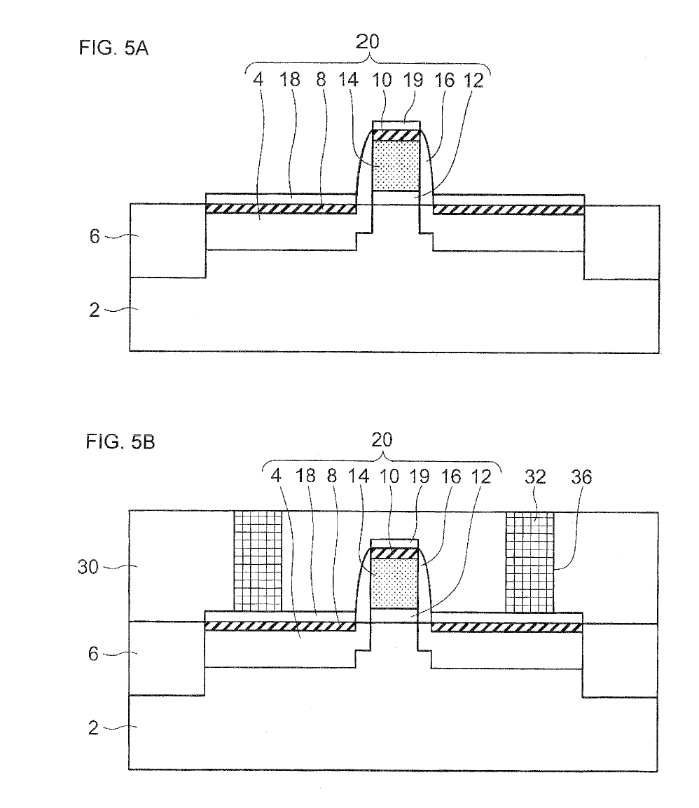

Then, the metal cap films 18 and 19 are selectively grown on the Ni silicide films 8 and 10 as shown in FIG. 5A, respectively. Conditions for the selective growth will be described as follows.

The selective growth is executed through three steps of a first step, a second one, and a third one. The first step is a step for pre-cleaning. At the first step, for example, the oxide film on the Ni silicide layer is removed with diluted hydrofluoric acid, and subsequently, the surface is cleaned, using an ammonium fluoride solution. The second step is a step for seeding. At the second step, a preprocessing is performed between about 30 degrees and about 60 degrees, using, for example, a palladium solution. The third step is a step for selective growth. At the third step, for example, an organoalkaline Co solution added with W and P is applied, and a cap metal film is formed at depo rate of from about 20 A/minute to about 200 A/minute.

Moreover, palladium in the palladium solution used for the preprocessing is introduced into the metal cap films 18 and 19 during the selective growth.

Here, there is obtained excellent selective growth of the metal cap film onto the Ni silicide film in the above selective growth process because Ni constituting the Ni silicide film and palladium belong to the same family in the periodic table. In addition, Co as a main component of the metal cap film, and Ni included in the Ni silicide film are included in families, adjacent to each other, (Co is the ninth family, and Ni is the tenth family.), in the periodic table, respectively. The Co and the Ni has a similar physical metallurgy. Accordingly, there is obtained excellent selective growth of the metal cap film onto the Ni silicide film.

Then, there is formed an insulating interlayer 30, as shown in FIG. 5B, on the N-channel transistor 20 and the element isolation insulation film 6. A contact hole 36 is opened in the insulating interlayer 30, and, a contact plug 32 connected to the N-type diffusion layer 4 through a Ni silicide layer 8 and a metal cap layer 18 is formed in the contact hole 36.

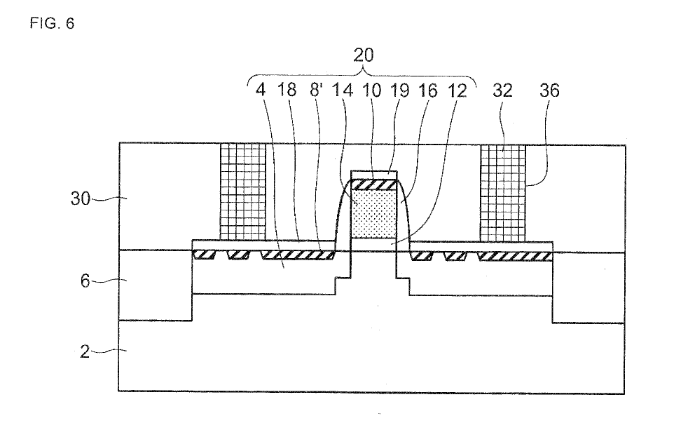

At this time, by heat-treating (annealing processing after ion injection after opening the contact hole, heat processing caused by formation of barrier metal before formation of the contact plug, and the like) after opening the contact hole 36, the Ni silicide film 8 on the N-type diffusion layer 4 causes the agglutination reaction, as shown in FIG. 6, to cause Ni silicide layers 8′ divided into parts by the N-type diffusion layer 4.

From the structure of FIG. 5B, the interconnect 34 connected to the contact plug 32 is further formed on the insulating interlayer, and the semiconductor device 100 shown in FIG. 1 is obtained.

Then, the effects according to the present exemplary embodiment will be described as follows.

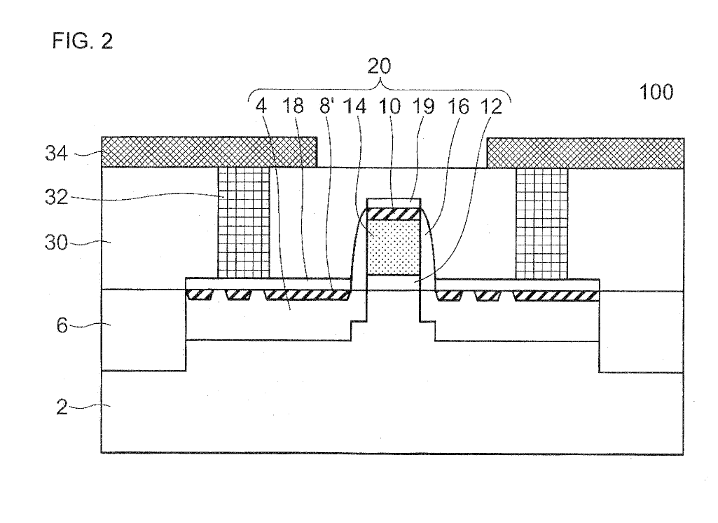

In the present exemplary embodiment, even in a case in which the Ni silicide layer 8′ on the N-type diffusion layer 4 causes the agglutination reaction and is divided into parts by the N-type diffusion layer 4, as shown in FIG. 2, a low layer resistance can be stably obtained because the Ni silicide layer 8′ is electrically connected through a metal cap film 18 selectively provided on the upper layer of the Ni silicide layer 8′. Furthermore, the thermal resistance of the Ni silicide layer is improved by adding Pt to the Ni silicide layer, and there is caused an improvement in a temperature at which there is no increase in the resistance by heat processing.

### Second Exemplary Embodiment

Then, a second exemplary embodiment according to the present invention will be explained, referring to drawings.

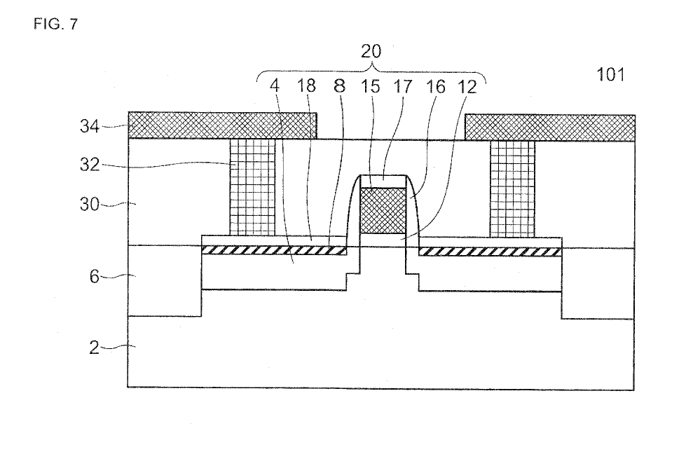

FIG. 7 is a view showing the second exemplary embodiment of the present invention. It is different from the configuration of the first exemplary embodiment that a gate electrode 15 of an N-channel transistor 20 in a semiconductor device 101 is formed with metal, as shown in FIG. 7 in the present exemplary embodiment. Furthermore, as a cap insulation film 17 is provided on the metal gate electrode 15 in the present exemplary embodiment, neither the Ni silicide layer nor the metal cap film are formed on the metal gate electrode 15, different from the configuration of the first exemplary embodiment. The cap insulation film 17 includes, for example, a silicon nitride film. Here, even in the present exemplary embodiment, the Ni silicide layer may include Pt.

Then, the method of manufacturing the present exemplary embodiment will be explained.

The method of manufacturing the present exemplary embodiment is the same method as that of the first exemplary embodiment, except that there is formed a gate electrode by patterning a two-layer structural film of the metal layer and the cap insulation film for forming a gate electrode.

Then, the effects of the present exemplary embodiment will be described as follows.

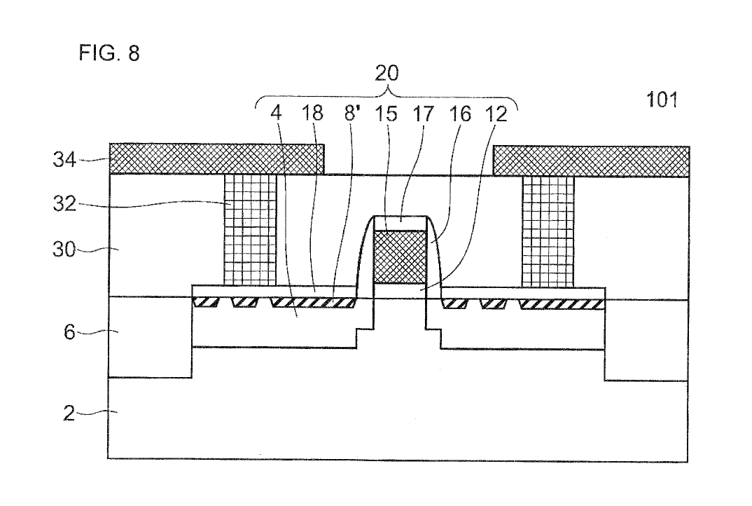

Even in the present exemplary embodiment, a low layer resistance can be stably obtained because the Ni silicide layer 8′ is electrically connected through the metal cap film 18 selectively provided on the upper layer of the Ni silicide layer 8′ even in a case in which, as well as the first exemplary embodiment, the Ni silicide layer 8′ on the N-type diffusion layer 4 causes the agglutination reaction and is divided into parts by the N-type diffusion layer 4, as shown in FIG. 8. Moreover, deterioration in the transistor characteristics which is caused by depletion of the gate electrode, can be controlled because the gate electrode is formed with metal.

### Third Exemplary Embodiment

Then, a third exemplary embodiment according to the present invention will be explained, referring to drawings.

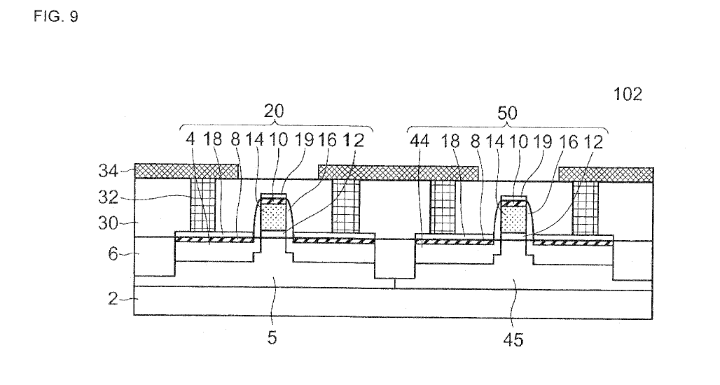

FIG. 9 is a view showing the third exemplary embodiment according to the present invention. In this exemplary embodiment, the present invention is applied to CMOS. Hereinafter, different points between the present exemplary embodiment and the first exemplary embodiment will be mainly described, and the same points as those in the first exemplary embodiment will not be repeated.

As shown in FIG. 9, a semiconductor device 102 has the N-channel transistor 20 provided on a P well 5 formed in the P-type substrate 2, and a P-channel transistor 50 provided on an N well 45 formed in the P-type substrate 2.

The N-channel transistor 20 has: the N-type diffusion layer 4; the Ni silicide layer 8 provided on the N-type diffusion layer 4; the gate insulation film 12; the gate electrode 14; a Ni silicide layer 10 formed on the gate electrode 14; and the side-wall insulation film 16 provided on the side wall of gate electrode 4.

The Ni silicide layer 8 is continuously provided on an N-type diffusion layer 204, and the metal cap film 18 (for example, CoWP) is selectively formed on the Ni silicide layer 8. Moreover, the cap metal film 19 (for example, CoWP) is selectively formed on the Ni silicide layer 10.

Moreover, the P-channel transistor 50 has: a P-type diffusion layer 44; a Ni silicide layer 8 provided on the P-type diffusion layer 44; a gate insulation film 12; a gate electrode 14; a Ni silicide layer 10 formed on the gate electrode 14; and the side-wall insulation film 16 provided on the side wall of the gate electrode 4.

The Ni silicide layers 8 is continuously provided on the P-type diffusion layer 44, and the cap metal film 18 (for example, the CoWP film) is selectively formed on the Ni silicide layer 8. Moreover, the cap metal film 19 (for example, CoWP film) is selectively formed even on the Ni silicide layer 10. Here, even in the present exemplary embodiment, the Ni silicide layer may include Pt.

Then, a method of manufacturing the present exemplary embodiment will be explained.

The method of manufacturing the present exemplary embodiment is the same as that of the first exemplary embodiment, except the following processes:forming a P-well 5, and an N-well 45; forming an N-type extension, using a photoresist, which covers a gate electrode 14 and an N well region, as a mask; forming a P-type extension, using a photoresist, which covers the gate electrode 14 and the P well region, as a mask; forming an N-type diffusion layer 4, using a photoresist covering the gate electrode 14, the side wall insulation film 16, and the N well region, as a mask; and forming the P-type diffusion layer 44, using a photoresist covering the gate electrode 14, the side wall insulation film 16, and the P-well region, as a mask.

Then, the effects of the present exemplary embodiment will be described as follows.

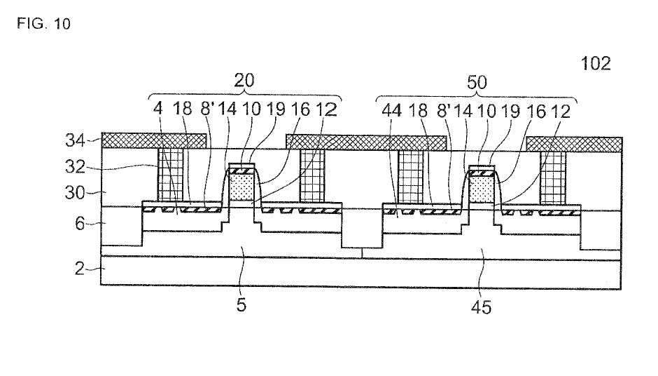

Even in the present exemplary embodiment, a low layer resistance can be stably obtained because the Ni silicide layer 8′ is electrically connected through the metal cap film 18 selectively provided on the upper layer of the Ni silicide layer 8′ even when, as well as the first exemplary embodiment, the Ni silicide layer 8′ on the N-type diffusion layer 4 causes the agglutination reaction to generate a state in which the Ni silicide layer 8′ is divided into parts by the N-type diffusion layer 4 as shown in FIG. 10, and even when the Ni silicide layer 8′ on the P-type diffusion layer 4 causes the agglutination reaction, and to generate a state in which the layer 8′ is divided into parts with the P-type diffusion layer 44.

### Fourth Exemplary Embodiment

Then, a fourth exemplary embodiment according to the present invention will be explained, referring to drawings.

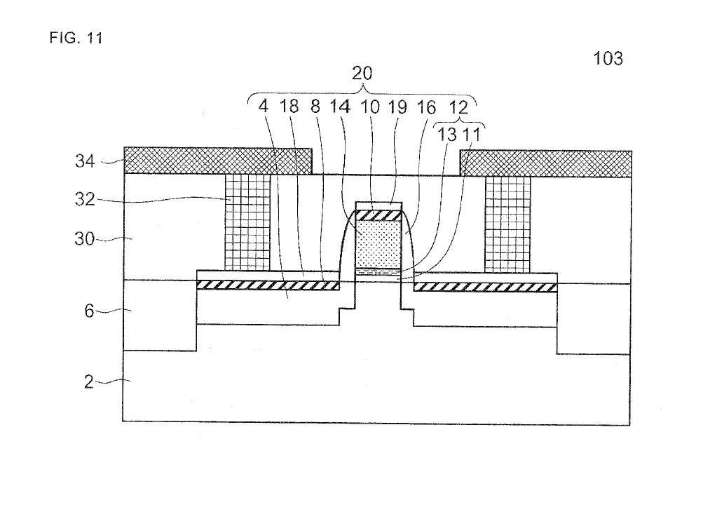

FIG. 11 is a view showing the fourth exemplary embodiment according to the present invention. The present exemplary embodiment is different from the first exemplary embodiment in a point that, as shown in FIG. 11, the gate insulation film 12 has a two-layer structure of a High-K film 13 and a SiON film 11. Here, even in the present exemplary embodiment, the Ni silicide layer may include Pt.

Then, a method of manufacturing the present exemplary embodiment will be explained.

A method of manufacturing the present exemplary embodiment is the same method as that of the first exemplary embodiment, except that the gate insulation film 12 is formed with a two-layer structure of the High-K film 13 and the SiON film 11.

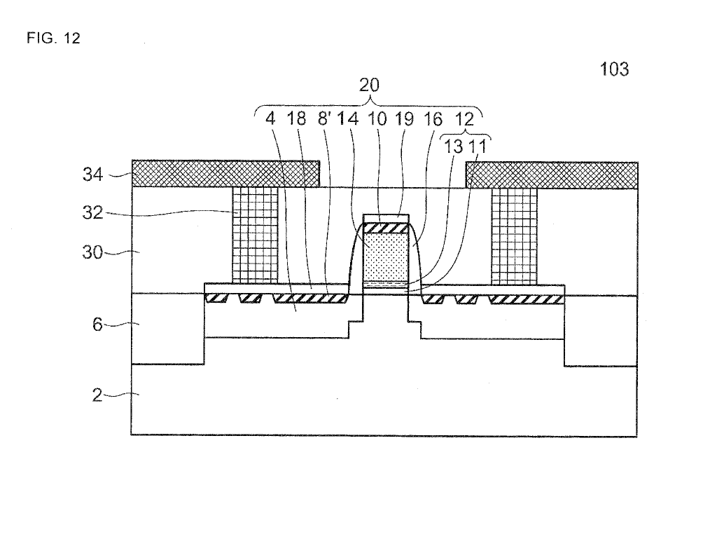

Even in the present exemplary embodiment, a low layer resistance can be stably obtained because the Ni silicide layer 8′ is electrically connected through the metal cap film 18 selectively provided on the upper layer of the Ni silicide layer 8′ even when, as well as the first exemplary embodiment, the Ni silicide layer 8′ on the N-type diffusion layer 4 causes the agglutination reaction to generate a state in which the Ni silicide layer 8′ is divided into parts by the N-type diffusion layer 4 as shown in FIG. 12. Furthermore, as the gate insulation film 12 has a two-layer structure of the High-K film 13 and the SiON film 11, the gate insulation film can be made thinner in terms of the oxide film.

### Fifth Exemplary Embodiment

Then, a fifth exemplary embodiment according to the present invention will be explained, referring to drawings.

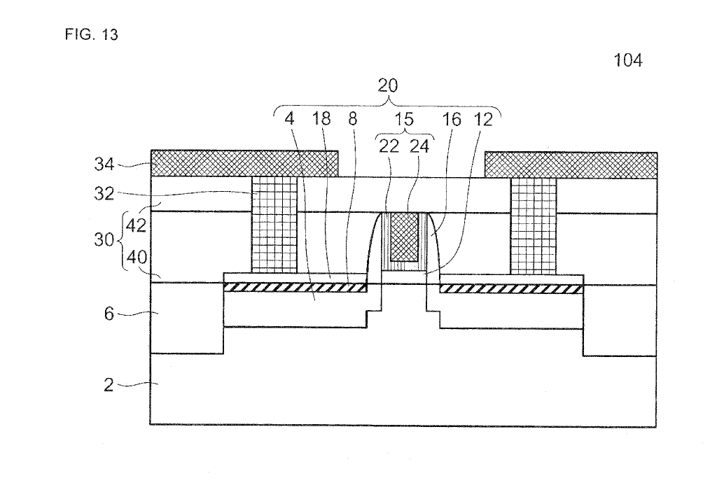

FIG. 13 is a view showing the fifth exemplary embodiment according to the present invention. In the present exemplary embodiment, a gate electrode 15 is formed with metal as well as the second exemplary embodiment. The present exemplary embodiment differs from the second exemplary embodiment in the following two points.

That is, a first point is that the metal gate electrode 15 includes a first metallic film 22 and a second metallic film 24, and, a second point is that, while the second exemplary embodiment uses a process (gate-first process) in which the gate electrode is formed at the beginning of transistor formation, the present exemplary embodiment uses a process (gate last process) in which the gate electrode is formed at the end of transistor formation.

As shown in FIG. 13, the first metallic film 22 forms the bottom portion and the sidewall portion of the metal gate electrode 15, and includes, for example, ruthenium. The second metallic film 24 is provided inside the first metallic film 24, and includes, for example, tungsten.

Moreover, even in the present exemplary embodiment, neither the Ni silicide layer nor the metal cap film is formed on the metal gate electrode 15 as well as the second exemplary embodiment. The reason is that, as the present exemplary embodiment uses the gate last process, formation of the Ni silicide layer, and, also, that of the metal cap film have been completed when the gate-electrode is formed. Here, even in the present exemplary embodiment, the Ni silicide layer may include Pt.

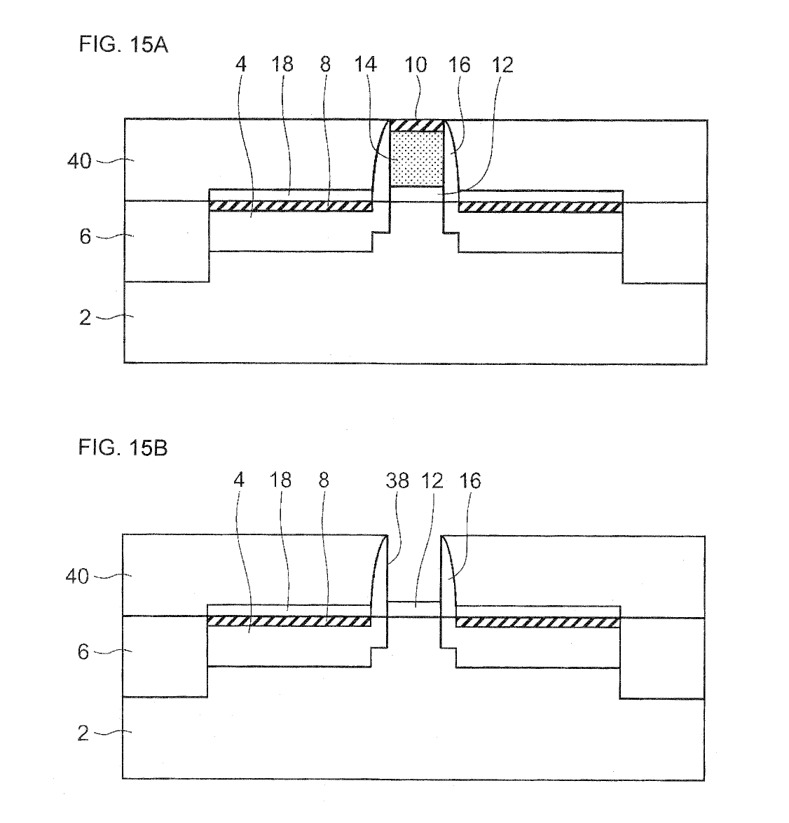

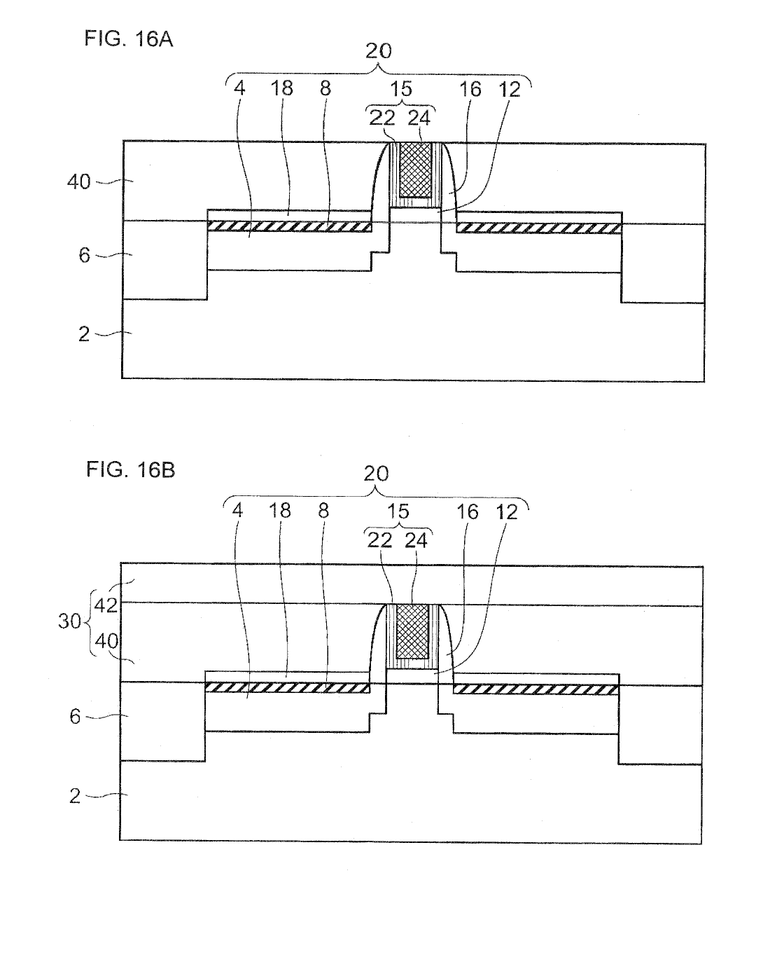

Subsequently, the method of manufacturing the present exemplary embodiment will be explained, referring to FIG. 15 and FIG. 16.

Firstly a first insulating interlayer 40 is formed on the P-type silicon substrate 2 as shown in FIG. 15A after forming the metal cap films 18 and 19 as shown in FIG. 5A. Subsequently, the insulating interlayer 40 is removed, by, for example, CMP (Chemical Mechanical Polishing) in such a way that the Ni silicide layer 10 is exposed.

Subsequently, the Ni silicide layer 10 and the polysilicon layer 14 are removed as shown in FIG. 15B to form a recess 38.

Then, the first metallic film 22 (for example, ruthenium film), and the second metallic film 24 (for example, tungsten film) are embedded in the recess 38, as shown in FIG. 16A.

Subsequently, a second insulating interlayer 42 is formed on the first insulating interlayer 40 as shown in FIG. 16B. Then, the contact plug 32 and the interconnect 34 are formed as well as the first exemplary embodiment, and there is obtained a semiconductor device 104 shown in FIG. 13.

Subsequently, the effects of the present exemplary embodiment will be described as follows.

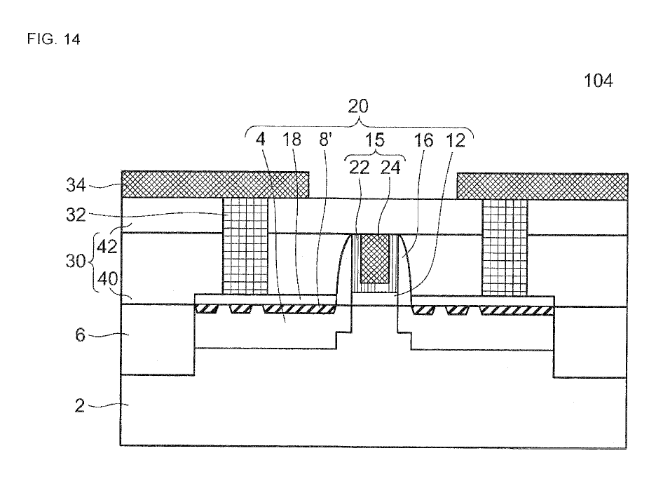

Even in the present exemplary embodiment, a low layer resistance can be stably obtained because the Ni silicide layer 8′ is electrically connected through the metal cap film 18 selectively provided on the upper layer of the Ni silicide layer 8′ even when, as well as the first exemplary embodiment, the Ni silicide layer 8′ on the N-type diffusion layer 4 causes the agglutination reaction to generate a state in which the Ni silicide layer 8′ is divided into parts by the N-type diffusion layer 4 as shown in FIG. 14.

Furthermore, deterioration in the transistor characteristics, which is caused by the gate-electrode depletion, can be suppressed because the gate electrode is formed with metal.

Moreover, as the gate electrode is formed at the end of the transistor formation using the gate last process (that is, the gate electrode is formed in such a way that the recess is buried), the gate electrode with a desired shape can be easily formed even when a material (for example, ruthenium), which is difficult to be etched, is used for the gate electrode.

### Sixth Exemplary Embodiment

Then, a sixth exemplary embodiment according to the present invention will be explained, referring to drawings.

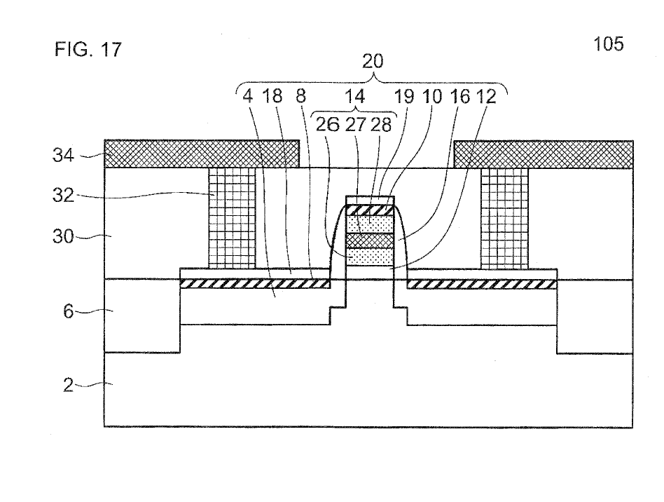

FIG. 17 is a view showing the sixth exemplary embodiment of the present invention. The present exemplary embodiment is different from the first exemplary embodiment in a point that the gate electrode 14 of the N-channel transistor 20 in a semiconductor device 105 has a three-layer structure (MIPS structure) of a polysilicon film 26, a metal film 27, and a polysilicon film 26 in this order from the lower layer as shown in FIG. 17. The sixth exemplary embodiment is similar to the first exemplary embodiment in other configuration.

Moreover, even in the present exemplary embodiment, a Ni silicide layer 10 and a metal cap film 19 are formed on the gate electrode 14 as well as the first exemplary embodiment. Here, even in the present exemplary embodiment, the Ni silicide layer may include Pt.

Subsequently, a method of manufacturing the present example will be explained.

The method of manufacturing the present example is similar to that of the first exemplary embodiment, except point that the gate electrode is formed by patterning for forming a gate electrode. The patterning is executed for a three-layer-structure film of a polysilicon film, a metal film, and a polysilicon film in this order from the lower layer.

Then, effects of the present exemplary embodiment will be described as follows.

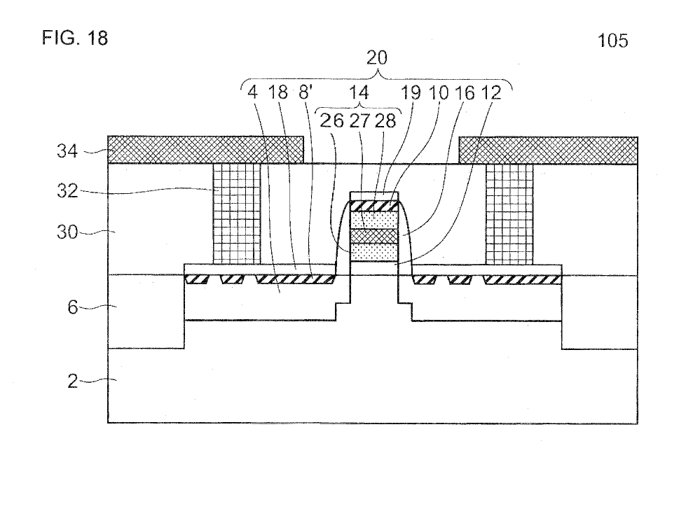

Even in the present exemplary embodiment, a low layer resistance can be stably obtained as well as the first exemplary embodiment, because the Ni silicide layer 8′ is electrically connected through the metal cap film 18 selectively provided on the upper layer of the Ni silicide layer 8′ even when the Ni silicide layer 8′ on the N-type diffusion layer 4 causes the agglutination reaction to generate a state in which the Ni silicide layer 8′ is divided into parts by the N-type diffusion layer 4 as shown in FIG. 18.

Moreover, as the gate electrode has a three-layer structure (MIPS structure) of the polysilicon film 26, the metal film 27, and the polysilicon film 26 in this order from the lower layer, deterioration of the transistor characteristic, which is generated by gate-electrode depletion, can be suppressed by the metal film 27 as a middle layer, and, at the same time, a stress applied to the gate insulation film can be relieved because the whole area of the gate electrode is not formed with metal.

Though exemplary embodiments have been explained as described above, referring to drawings, the present invention is not limited to the exemplary embodiments, and various and modifications may be possible.

Combinations of, for example, the exemplary embodiments can be applied.

Concretely, “the gate insulation film with the two-layer structure of a High-K film and a SiON film” illustrated in the fourth exemplary embodiment may be combined with any one of the second exemplary embodiment, the third exemplary embodiment, the fifth exemplary embodiment, and the sixth exemplary embodiment.

Moreover, the CMOS structure illustrated in the third exemplary embodiment may be combined with any one of the second exemplary embodiment, the fifth exemplary embodiment, and the sixth exemplary embodiment.

It is apparent that the present invention is not limited to the above exemplary embodiment, and may be modified and changed without departing from the scope and spirits of the invention.

What is claimed is:

1. A semiconductor device, comprising:
a semiconductor substrate;
a diffusion layer provided in said semiconductor substrate;
a gate insulation film provided over said semiconductor substrate;
a gate electrode provided over said gate insulation film; and
a metallic silicide layer having Ni as a main component which is selectively provided over said diffusion layer,
wherein a metal cap film having Co as a main component, is selectively provided over said silicide layer.

2. The semiconductor device according to claim 1,
wherein said metallic silicide layer further includes Pt.

3. The semiconductor device according to claim 1,
wherein said silicide layer is divided into a plurality of regions by said diffusion layer, and, at the same time, said metal cap film is provided even over the diffusion layer by which said silicide layer is divided into said plurality of regions.

4. The semiconductor device according to claim 1,
wherein said silicide layer is divided into a plurality of regions by said diffusion layer, and at the same time,
said silicide layers provided in said plurality of regions are connected through said metal cap film.

5. The semiconductor device according to claim 1, further comprising:
a side wall insulation film provided over the side wall of said gate electrode; and
a metallic silicide layer having a second Ni as a main component which is provided over said gate electrode, and;
wherein said metal cap film is selectively provided over said second silicide layer provided over said gate electrode.

6. The semiconductor device according to claim 1,
wherein said gate insulation film includes a High-k film.

7. The semiconductor device according to claim 1,
wherein said gate insulation film is a two-layer structural film of a SiON film and a High-k film.

8. The semiconductor device according to claim 1,
wherein said metal cap film includes W and P.

9. The semiconductor device according to claim 7,
wherein said metal cap film includes palladium belonging to the same group in the periodic table as Ni included in said silicide layer.

10. A method of manufacturing a semiconductor device, comprising:
forming a gate insulation film over a semiconductor substrate;
forming a gate electrode over said gate insulation film;
forming a diffusion layer in the neighborhood of said gate electrode;
forming selectively a metallic silicide layer having Ni as a main component over said diffusion layer; and
growing selectively a metal cap film having Co as a main component over said metallic silicide layer.

11. The method of manufacturing a semiconductor device according to claim 10,
wherein said metallic silicide layer further includes Pt.

12. The method of manufacturing a semiconductor device according to claim 10,
wherein said step of growing selectively a metal cap film, comprises:
preprocessing during which a palladium solution is applied; and
growing selectively during which an alkali solution including Co being a main component of said metal cap film, is applied.

13. The method of manufacturing a semiconductor device according to claim 10, further comprising:
forming a side wall insulation film over the side wall of said gate electrode;
forming selectively a metallic silicide layer having a second Ni as a main component, over said gate electrode; and
growing selectively said metal cap film over said second silicide layer.

14. The method of manufacturing a semiconductor device according to claim 10,
wherein said step of forming a gate insulation film includes forming a High-k film.

15. The method of manufacturing a semiconductor device according to claim 10,
wherein said step of forming a gate insulation film includes forming a SiON film, and forming a High-k film.

16. The method of manufacturing a semiconductor device according to claim 10,
wherein Ni included in said silicide layer belongs to the same group in the periodic table as palladium used in said step of preprocessing.

17. The method of manufacturing a semiconductor device according to claim 10,
wherein said metal cap film includes W and P.
